(19) United States
(12) Patent Application Publication
(10) Pub. No.: US 2004/0247789 A1
(43) Pub. Date: Dec. 9, 2004

(54) Method of globally repairing a part covered with a thermal barrier

(76) Inventors: Bruno Gilles Francois Boucard, Les Retinieres (FR); Jean-Paul Fournes, Dannemois (FR); Andre Hubert Louis Malie, Chatellerault (FR); Denis Georges Manesse, Chatellerault (FR); Guillame Roger Pierre Oberlander, Paris (FR); Catherine Marie-Helene Richin, Roinville Sous Dourdan (FR)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/488,295

(22) PCT Filed: Jul. 11, 2002
(86) PCT No.: PCT/FR02/02436

(30) Foreign Application Priority Data
Jul. 12, 2001 (FR) 01/09258

(51) Int. Cl. C23C 16/00

(52) U.S. Cl. 427/253

(57) ABSTRACT

The invention relates to a method of overall repair for a part (1) coated in a thermal barrier constituted by a ceramic outer layer (5) and a metal underlayer (3) of alumina-forming alloy, the method being characterized by the following steps: a) subjecting the metal part (1) for repair to thermochemical treatment under fluorine-containing halogen gas for a length of time that is sufficient to eliminate the aluminum contained in the underlayer (3) and any oxides and sulfur compounds that might be present at the surface of the part (1) and in cracks (6), thereby causing the ceramic layer (5) to be removed and causing the part (1) to be passivated; b) restoring mechanical integrity to the part (1) by methods of repairing any cracks (6) by adding material; c) enriching the surface of the part in aluminum, if necessary; and d) depositing a new layer (5) of ceramic. The invention is particularly applicable to the blades of the high pressure turbine of a turbomachine.

The invention relates to overall repair of parts coated in a thermal barrier and subjected to a hostile environment, such as the nozzles and the moving blades of high pressure (HP) turbines in turbomachines, in particular for aviation.

The continuing improvement in the efficiency of modern gas turbines requires ever-increasing design temperatures at turbine inlets. This trend has encouraged the development of ever more refractory materials for making the parts of the HP turbine such as blades and nozzles. For this purpose, single-crystal superalloys with very high volume fractions of gamma prime hardening phase have been developed. The development of superalloys is no longer sufficient to keep up with the ever-increasing requirements in terms of the lifetimes of parts at high temperatures. Thus, more recently, parts have been brought into operation that are coated in thermal insulation in order to lower the temperature of the metal of such parts which are cooled by internal convection.

Such thermally insulating coatings, referred to as thermal barriers, are constituted by an outer layer of zirconia-based ceramic stabilized by yttrium oxide, or “yttria”, deposited on a bonding metal underlayer for enabling the ceramic coating to adhere while also protecting the metal of the part from oxidation.

The ceramic outer layer of the thermal barrier is deposited by a method consisting in vaporizing the material by means of an electron beam, a plasma electric arc, or a power laser beam, with the vapor subsequently becoming deposited on the part and on the walls of the enclosure in which the part is exposed to the vapor. When that method is used for depositing ceramic, the ceramic is in columnar form which provides better resistance to thermal shocks.

The metal underlayers of the thermal barrier can be of various types.

Mention can be made firstly of underlayers of the MCrAlY type (where M designates nickel or cobalt) which consists in a gamma matrix of nickel-cobalt with chromium in solution containing beta precipitates of NiAl. Such underlayers are deposited either by evaporating their components under electron bombardment, or by thermal spraying.

Mention can also be made of underlayers of the aluminide type (NiAl) of intermetallic structure, compounds comprising 50 atomic percent each of nickel and of aluminum. Such coatings are obtained by thermochemical methods of aluminization. In this category, aluminide coatings modified by a precious metal such as platinum (Ni₍₁₋ₓ₎PtₓAl) constitute preferred underlayer systems. In such systems, platinum is in insertion in the nickel sub-lattice. The platinum is deposited electrolytically before the thermochemical treatment for aluminization. Aluminide coatings are made up of an outer layer formed by deposition and a deeper layer diffused into the substrate. The precious metal is contained mainly in the outer layer of the aluminide coating.

It should be observed that MCrAlY underlayer systems exist in which the surface is modified by a precious metal. For this purpose, platinum is deposited electrolytically on the surface of the MCrAlY layer and then diffused to a depth of about 10 micrometers (μm) by heat treatment under an inert atmosphere.

Finally, mention can be made of underlayer systems which consist in modifying the surface of the superalloy of the part by depositing a relatively thick (>10 μm) layer of platinum followed by diffusion heat treatment.

All of those underlayer systems have as their common denominator the feature of being alumina-forming, i.e. on becoming oxidized they form a protective film of alumina that adheres to the metal and isolates it from the oxidizing surroundings. The alumina film formed by the underlayers serves as a bonding layer for the ceramic coating and performs a function of protecting the substrate against oxidation.

The addition of precious metals such as platinum to protective coatings and to thermal barrier underlayers has the effects of improving the quality of the layer of alumina that is formed and of promoting its adhesion to the metal. Nevertheless, the addition of platinum leads to a significant increase in cost.

Heat treatments enable metal to diffuse between the underlayer and the substrate on which it is deposited. A diffused layer is thus created at the interface between the underlayer and the substrate.

The fixed and moving blades of high pressure turbines in turbojets in particular are subjected to extremely severe conditions, temperatures and temperature variations, and also chemical aggression or aggression due to impacts from particles ingested by the engine. Certain zones of the blades can become damaged, in particular their leading edges and their trailing edges. Cracks can be produced in the part, and the outer layer can disappear locally, possibly together with the underlayer, leading to the part being oxidized. Given the high cost of a new part, such damage can require the part to be repaired totally, which consists in removing the old thermal barrier, cleaning the part, then reconstituting it, and then rebuilding a new thermal barrier.

In order to repair a part such as a turbine nozzle coated in a thermal barrier, it is known that the ceramic coating needs to be removed and then the metal underlayer. Thereafter, the part must be deoxidized by thermochemical treatment under a halogen atmosphere which has the property of cleaning the insides of the cracks prior to brazing. The part can then be repaired by a welding and/or brazing technique. Once the part has been refilled and restored to its design dimensions by a method of machining for removing material, e.g. by using an abrasive strip, a grinder, etc., depending on the shape of the part, the metal underlayer and then the outer ceramic layer are rebuilt.

The thermal barrier is conventionally removed by sandblasting. Sandblasting is an operation which is aggressive both to the ceramic layer and to the underlayer. Removing the ceramic layer leads to the underlayer also being removed in part. Care must be taken to stop the sandblasting operation soon enough to avoid removing the underlayer completely, since that would lead to material being removed from the substrate. The remainder of the underlayer is then removed by chemical dissolution in an acid bath. That operation is difficult since it leads to the diffused layer of the aluminide coating being dissolved and effectively leads to the wall thicknesses of the part being reduced.

Techniques for removing thermal barriers are thus difficult and poorly optimized since:

they lead to a reduction in web thicknesses of parts, whether the term “web” means a thin wall of a part;

they require at least two operations, one for the ceramic outer layer and the other for the underlayer; and

if the outer layer concerned contains a precious metal, it is purely and simply lost when the underlayer is eliminated.

The operation of rebuilding the underlayer thus requires new precious metal to be deposited and then requires the part to be aluminized prior to depositing the ceramic layer.

U.S. Pat. No. 5,614,054 describes a method of removing a thermal barrier which consists in heating the coated part in a halogen atmosphere. That patent limits the application of the method solely to removing the ceramic layer and does not suggest that the method could be continued in order to process the underlayer and any cracks that might be present.

U.S. Pat. No. 5,728,227 teaches a technique of removing protective coatings of diffused aluminides, which technique consists in mechanically removing the outer layer and in removing the aluminum of the diffused layer by heating the part in the presence of a halogen atmosphere. That technique of removing aluminide coatings applied to removing the underlayers of thermal barriers can indeed avoid reducing web thickness of the parts. It complicates the operation of removing the underlayer insofar as two operations, one mechanical and the other thermochemical are needed in order to remove the underlayer. Finally, for an underlayer containing precious metal, that techniques leads to the precious metal being lost, which metal, it will be recalled, is contained mainly in the outer layer of the underlayer.

Thus, present methods for overall repair of a part coated in a thermal barrier constituted by a columnar ceramic outer layer and an alumina-forming alloy underlayer comprise at least the following seven steps:

1) removing the ceramic outer layer;

2) removing the metal underlayer;

3) depassivating the part, which consists in removing oxides, sulfur compounds, etc. that form at high temperature in contact with combustion gases, so as to obtain metal that is suitable for brazing. Good depassivation gives the surface of the part wetting ability which enables brazing material to penetrate well into the cracks and gives good adhesion to brazing and welding;

4) repairing any cracks by applying material, e.g. by depositing brazing powder and then passing through an oven. When the part is nicked or eroded, e.g. at the tip, the leading edge, or the trailing edge of a blade, then the shape of the part is reconstituted by building it out with material;

5) reconstructing the underlayer by depositing the materials that constitute it: NiAl, MCrAlY, Pt, etc., and performing diffusion treatment in an oven;

6) diffusion aluminization of the underlayer; and

7) depositing the ceramic outer layer of the thermal barrier.

It should be observed that removing the metal underlayer leads to a loss of any precious metal contained therein and to a risk of web thickness of the part being decreased.

The risk of reduction in web thickness is so high that a given turbine blade can be repaired by present-day techniques only a very limited number of times, and sometimes only twice when the web is very thin.

A first object of the invention is to provide a repair method which avoids decreasing web thicknesses of the part.

A second object of the invention is to reduce the number of operations needed to repair a part coated in a thermal barrier.

A third object of the invention is to propose a method which avoids eliminating the precious metals of the metal underlayer and the subsequent requirement of applying new precious metal.

The method of the invention is characterized by the following steps:

a) subjecting the metal part for repair to thermochemical treatment under fluorine-containing halogen gas for a length of time that is sufficient to eliminate the aluminum contained in the underlayer and any oxides and sulfur compounds that might be present at the surface of the part and in cracks, thereby causing the ceramic layer to be removed and causing the part to be passivated;

b) restoring mechanical integrity to the part by methods of repairing any cracks by adding material;

c) enriching the surface of the part in aluminum, if necessary; and

d) depositing a new layer of ceramic.

At the beginning of the first step, the fluorine-containing halogen gas penetrates into the ceramic via its pores, whereupon it attacks the yttria of the ceramic, thereby increasing porosity and encouraging further penetration of the fluorine-containing halogen gas. Continued thermochemical treatment under fluorine-containing halogen gas causes aluminum to be eliminated from the metal underlayer and from the layer diffused into the periphery of the substrate. By eliminating aluminum during the first step, the bonds between the metal underlayer and the bottoms of the columns in the ceramic outer layer disappear, thereby encouraging the ceramic outer layer to flake off (“spall”) during subsequent cooling of the part. All that remains of the underlayer is then the precious metals, i.e. the nickel and the platinum of said underlayer which has been transformed into a metal sponge. In the zones where the part has cracks, metal oxides are also eliminated by the fluorine-containing halogen gas. Thermochemical attack by means of the fluorine-containing halogen gas performs effective depassivation. Nevertheless, such attack should not be continued too far since that would lead to damage between the grains of the metal constituting the part and would encourage the appearance of new cracks.

The first object is achieved by the fact that the part is chemically prepared for refilling with brazing or welding material, without material being removed from the part.

The second object is achieved by the fact the part is prepared to being refilled with welding or brazing material in a single thermochemical treatment operation under fluorine-containing halogen gas. It will be understood that the aluminum of the underlayer is removed by the thermochemical attack from the fluorine-containing halogen gas passing through the ceramic layer. It will also be understood that the part is depassivated by the thermochemical attack from the fluorine-containing halogen gas passing simultaneously through the ceramic layer and the underlayer that is made porous by the removal of the aluminum constituting it.

The second object is also achieved by the fact that the operations of reconstituting the underlayer are omitted, all that remains being the operation of aluminization.

It is therefore not necessary to remove the underlayer in order to proceed with refilling material by welding or brazing. It suffices to remove the aluminum constituting the underlayer, which metal is known to be difficult to weld. It is found that during the welding or brazing operation, the added metal penetrates into the underlayer that has been made porous and bonds directly with the metal constituting the part.

It is not sufficient merely for the attack to be stronger than in the above-mentioned patents. The thermochemical attack must be sufficient to depassivate correctly the surface of the part under the thermal barrier and also the walls of the cracks, while nevertheless remaining limited so as to avoid damaging the grain boundaries in the metal of the part. The invention teaches that such a compromise is possible. The person skilled in the art will perform laboratory tests to establish on a case-by-case basis the appropriate quantity of thermochemical attack, as a function of the thermal barrier and of the metal of the part.

The third object is achieved by the fact that all of the materials constituting the underlayer, and in particular the precious metals such as platinum or palladium remain in place, with the exception of the aluminum and of yttrium.

At the end of the first step, any cracks have been cleaned and they are refilled during the second step by welding or brazing techniques.

Prior to rebuilding the thermal barrier, it suffices to enrich the surface of the part with aluminum. This aluminum fills the cavities in the metal sponge and enables a new layer of ceramic to be deposited. An external application of aluminum is necessary when NiAl underlayers are used, since they have a large fraction of Al. In contrast, when MCrAlY underlayers are used, in which the proportion of Al is much lower, it can happen that the aluminum which rises from the substrate by diffusion suffices.

Advantageously, the surface of the part is enriched in aluminum by a thermochemical method of pack or vapor aluminization.

Preferably, prior to enriching the surface of the part in aluminum, a step is performed of consolidating the residual metal sponge that results from the thermochemical treatment of the metal underlayer under fluorine-containing halogen gas. This consolidation is performed by light sandblasting, for example, i.e. sandblasting that is sufficient to reduce the pores of the underlayer by compression but not too strong in order to avoid removing the underlayer.

The method of the invention is particularly applicable for repairing high pressure turbine elements of a turbomachine, said elements being made of a nickel-based superalloy.

Other advantages and characteristics of the invention appear on reading the following description given by way of way of example and made with reference to the accompanying drawings, in which:

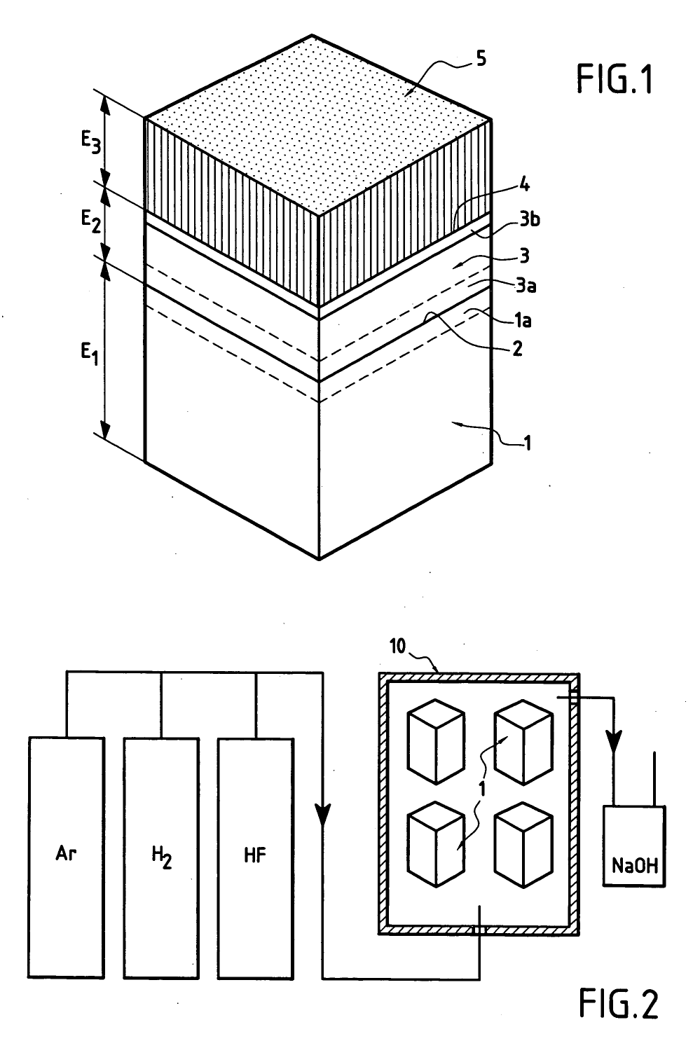

FIG. 1 shows a portion of a part in good condition coated with a thermal barrier of column type;

FIG. 2 shows the method of cleaning the part in order to remove the aluminum and oxides from cracks in the part;

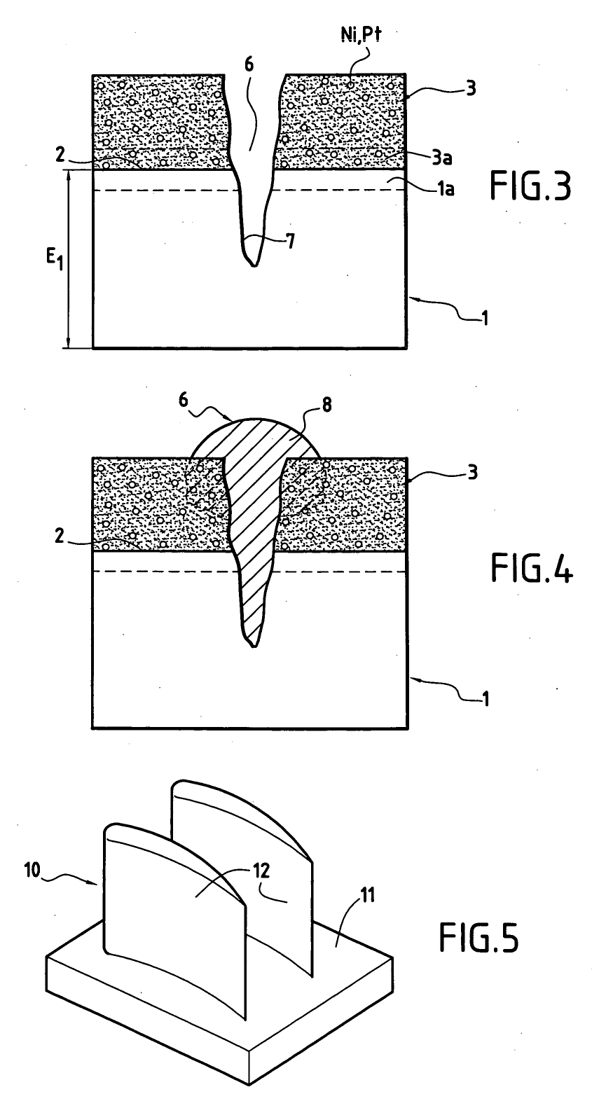

FIG. 3 is a section view through a portion of the part after the cleaning operation and after removing the ceramic layer;

FIG. 4 shows a crack and its environment after being refilled with brazing; and

FIG. 5 shows a vane sector of a turbine stator.

FIG. 1 shows a portion of a part 1 in good condition made of a nickel-based superalloy of thickness E1, coated on its outside face 2 in a metal underlayer 3 of alumina-forming alloy, whose own outside face 4 is itself coated in an outer layer 5 of columnar ceramic, of thickness E3.

By way of example, the part 1 is an element of a high pressure turbine nozzle of a turbojet, the element comprising a plurality of fixed vanes, or it could be a moving blade for this type of machine.

The role of the metal underlayer 3 is to protect the part 1 against oxidation and against corrosion that can be caused by the hot and aggressive gases flowing through the turbine. It also has the role of enabling the outer layer 5 of ceramic to be held in place.

The underlayer is made by depositing nickel or an MCrAlY alloy where M designates the metals of the part such as nickel or cobalt. Deposition is performed by spraying with a plasma torch or by the electron beam physical vapor deposition (EP-PVD) method which consists in depositing vapor under electron bombardment. The underlayer is subsequently coated in aluminum by pack or gas cementation. The underlayer may also include precious metals such as platinum Pt, palladium Pa deposited electrochemically. By means of heat treatments, metal and in particular nickel is caused to diffuse from the part 1 towards the underlayer 3 and aluminum diffuses from the underlayer 3 towards the part 1. The outside face 2 of the part 1 is at the interface between an outer zone 1a of the superalloy part 1 into which aluminum has been able to diffuse from the underlayer 3, and an inner zone 3a of the underlayer 3 into which metal from the substrate 1 has been able to diffuse. The underlayer 3 also presents close to the outside face 4 an alumina film 3b that is impermeable to oxygen and that bonds to the outer layer 5 of ceramic.

The outer layer 5 is made by evaporation under electron bombardment of a zirconia-based oxide that is partially or completely stabilized by adding yttrium oxide.

The thickness E3 of the outer layer 5 lies in the range 200 μm to 300 μm, and is typically 300 μm.

The part 1 coated in this way by the metal underlayer 3 and the ceramic outer layer 5 can be subjected to considerable damage in operation due to thermal shocks, to flaking of the outer layer 5, to oxidation of the underlayer 3, and to erosion by impacts against particles. Cracks may also occur in the metal underlayer 3 and the substrate of the part 1. The walls of the cracks are then subjected to considerable corrosion and oxidation. The part 1 then needs to be repaired, and the cracks need to be refilled with metal after they have been cleaned.

The invention provides a method of eliminating the outer ceramic layer 5, eliminating the alumina film contained in the underlayer 3, and also eliminating the aluminum contained in said underlayer 3 and in the outer zone 1a of the part 1, and eliminating oxides from cracks, all in a single step.

To do this, the part 1 is exposed to heat treatment under a fluorine-containing halogen gas for a length of time that is sufficient to eliminate all of the aluminum, and the oxides, but not too long in order to avoid etching between the grains of the substrate 1.

The fluorine-containing gas passes between the ceramic columns, thereby degrading the ceramic which further encourages penetration, thereby reaching and dissolving the alumina film 3b. This makes it possible subsequently to separate the outer layer 5 from the underlayer 3 during cooling of the part 1 after heat treatment. The fluorine-containing gas then reaches the underlayer 3 and also dissolves the aluminum and the alumina contained in the underlayer 3.

The progressive elimination of the aluminum and the alumina create pores in the underlayer 3 enabling the fluorine-containing gas to penetrate deeper into the underlayer 3, but it leaves the precious metals such as nickel and platinum in place which then form a porous layer that is permeable to the fluorine-containing gas. Finally, the fluorine-containing gas passes through the underlayer 3 once it has become porous and transformed into a metal sponge, thereby reaching the substrate 1, where upon it penetrates into the cracks and dissolves the oxides at the surface of the substrate and on the walls of the cracks. The substrate 1 and its cracks are thus cleaned through the thermal barrier without it being necessary to remove the thermal barrier completely.

By way of example, the part may be a vane sector for a stator made of single-crystal structure NTa8CKWA, where this nickel-based superalloy is commonly referred to as AM1. The thermal barrier includes a 60 μm thick underlayer of platinum-enriched (Pt) nickel aluminide (NiAl). The columnar ceramic layer of zircon enriched with 8% by weight ytrria (ZrO₂+Y₂O₃) is of thickness lying in the range 100 μm to 150 μm depending on position on the part. Thermochemical attack is performed at 975° C. for 1 hour (h) 30 minutes (min) using HF diluted to 10% in H₂.

FIG. 2 shows an installation for cleaning parts 1 placed in a leaktight enclosure 10 fed with a fluorine-containing halogen gas containing hydrogen, hydrofluoric acid, and an inert gas such as argon. Instead of coming from hydrofluoric acid, the fluorine may also come from decomposing Teflon or ammonium fluoride. Depending on circumstances, it is possible to add hydrogen H₂ in order to reduce any traces of oxygen that might be present in the oven during the thermochemical treatment. The parts 1 are subjected to a temperature close to 1000° C. during the cleaning treatment.

After the parts 1 have been cleaned, the ceramic becomes detached as the parts are cooling down at the end of the thermal cycle. It should be observed that light sandblasting is sometimes needed to remove shreds of ceramic that have remained in place.

FIG. 3 shows the appearance of a portion of a part 1 after the cleaning operation using a fluorine-containing halogen gas and after removal of the ceramic outer layer 5. The underlayer 3 comprises precious metals only such as nickel and platinum and it is porous. The layer 3b of alumina has disappeared. Reference 6 designates a crack whose walls 7 have been cleaned.

Thereafter, the cracks 6 are detected and they are repaired by a method of refilling by brazing and diffusion. This method consists in depositing brazing material on the cracks 6, and then in causing the components thereof to melt under a flame, and preferably an electric arc. Thereafter diffusion with the metal of the substrate 1 is performed by heat treatment.

FIG. 4 shows the environment of the crack 6 after the refilling operation. The crack 6 is full of brazing material which reaches the substrate 1 through the porous underlayer 3 in zones adjacent to the crack 6. The dome 8 of brazing material is subsequently flattened, e.g. by means of a strip sander.

The following step consists in densifying the sponge 3 made up of precious metals by light sandblasting. This densification operation is optional. Densification serves to reduce the residual pores which would otherwise weaken the underlayer 3 and encourage oxidation. The sandblasting is advantageously performed by projecting microbeads that achieve better compression of the underlayer 3 without tearing it away from the surface.

The third step consists in aluminizing the underlayer 3 in the porous or densified state. Aluminum is deposited by the pack or vapor cementation method. For aluminization, an activator is used such as ammonium fluoride or ammonium chloride which, together with aluminum, constitutes an intermediate compound enabling deposition to take place. Under the effect of heat, the aluminum deposited on the spongy underlayer 3 diffuses through the pores, thereby enabling the aluminide to be made directly. At these temperatures hydrochloric acid or hydrofluoric acid has strong reducing power. New heat treatment enables the alumina film 3a to be made.

The last step of the method consists in creating a new outer layer of ceramic, as though the part 1 were a new part coated in an underlayer 3 of aluminide or MCrAlY. The ceramic is preferably deposited by evaporation under electron bombardment in order to recreate a columnar ceramic.

FIG. 5 shows a blade sector 10 of a turbine stator constituted by a base 11 and a few vanes 12. The base 11 is covered in a thermal barrier of MCrAlY plus stratified ceramic, while the vanes 12 are covered in a thermal barrier of NiAl plus columnar ceramic deposited by the EB-PVD method. Total removal of the thermal barrier by sandblasting is impossible with this type of part without also removing metal from the substrate. The method described herein is particularly advantageous and attack by fluorine-containing gas enables both types of thermal barrier to be removed in the same operation.

1. A method of overall repair for a part (1) coated in a thermal barrier constituted by a ceramic outer layer (5) and a metal underlayer (3) of alumina-forming alloy,
the method being characterized by the following steps:
a) subjecting the metal part (1) for repair to thermochemical treatment under fluorine-containing halogen gas for a length of time that is sufficient to eliminate the aluminum contained in the underlayer (3) and any oxides and sulfur compounds that might be present at the surface of the part (1) and in cracks (6), thereby causing the ceramic layer (5) to be removed and causing the part (1) to be passivated;
b) restoring mechanical integrity to the part (1) by methods of repairing any cracks (6) by adding material;
c) enriching the surface of the part in aluminum, if necessary; and
d) depositing a new layer (5) of ceramic.

2. A method according to claim 1, characterized by the fact that the surface of the part is enriched with aluminum by a thermochemical method of pack aluminization.

3. A method according to claim 1, characterized by the fact that the surface of the part is enriched in aluminum by a thermochemical method of vapor aluminization.

4. A method according to any one of claims 1 to 3, characterized by the fact that prior to the step of enriching the part in aluminum, a step is performed of consolidating the residual metal sponge that results from the thermochemical treatment of the metal underlayer under fluorine-containing halogen gas.

5. A method according to claim 4, characterized by the fact that the residual metal sponge is consolidated by light sandblasting.

6. A method according to any one of claims 1 to 5, characterized by the fact that the part for repair is an element (10) of a high pressure turbine of a turbomachine.

7. A method according to claim 6, characterized by the fact that the turbine element (10) is made of a nickel-based superalloy.

8. A method according to claim 6 or claim 7, characterized by the fact that the turbine element (10) is coated in a thermal barrier of NiAl plus columnar ceramic.

9. A method according to claim 6 or claim 7, characterized by the fact that the turbine element (10) is coated in a thermal barrier made of MCrAlY plus stratified ceramic.

10. A method according to claim 6 or claim 7, characterized by the fact that the turbine element (10) is coated in a thermal barrier made in part out of NiAl plus columnar ceramic and a part out of MCrAlY plus stratified ceramic.
